(19) United States
(12) Patent Application Publication
(10) Pub. No.: US 2005/0059211 A1
(43) Pub. Date: Mar. 17, 2005

(54) Method of manufacturing semiconductor device

(76) Inventor: Masahiro Yoshida, Tokyo (JP)

Correspondence Address: VOLENTINE FRANCOS, PLLC, Suite 150, 12200 Sunrise Vally Drive, Reston, VA, 20191, US

(21) Appl. No.: 10/854,432

(22) Filed: May 27, 2004

(30) Foreign Application Priority Data
Sep. 11, 2003 (JP) JP2003-319205

(51) Int. Cl. H01L 21/336

(52) U.S. Cl. 438/257

(57) ABSTRACT

There is provided a method of manufacturing a semiconductor device comprising steps of providing a semiconductor substrate, forming a gate oxide film over the semiconductor substrate, forming a stacked gate structure on the gate oxide film comprising a floating gate electrode and a control gate electrode with a gate insulating film interposed therebetween, forming a charge leak protect film comprising oxide film with a heat-treatment around the stacked gate structure on the gate oxide film so that the charge leak protect film becomes as thick as the gate oxide film, forming a side wall on a vertical surface of the charge leak protect film, and treating the charge leak protect film with a heat-treatment so that the charge leak protect film becomes thicker than the gate oxide film.

### BACKGROUND OF THE INVENTION

1. Field of the Invention

The present invention relates to a method of manufacturing a semiconductor device, and more particularly, to a method of manufacturing a non-volatile memory cell.

2. Description of Related Art

An example of structure of a non-volatile memory cell is shown in FIG. 8. This kind of semiconductor device is manufactured as follows.

That is, it is manufactured by steps of providing a semiconductor substrate, forming a gate oxide film 91 over the semiconductor substrate, and forming a stacked gate structure on the gate oxide film 91 comprising a floating gate electrode 92 and a control gate electrode 94 with a gate insulating film 93 interposed therebetween. And, after these steps, a charge leak protect film 83 comprising oxide film is formed with a heat-treatment around the stacked gate structure on the gate oxide film 91, wherein the charge leak protect film 83 is thicker than the gate oxide film 91. Thereby, base of the floating gate electrode 92 is surrounded with the thick charge leak protect film 83 in a horizontal plane. As a result, electric charge held in the floating gate electrode 92 does not leak out through edge portion of the base of the floating gate electrode 92 in direction along the horizontal plane (c.f. JP11-126833, JP2000-49340, JP2003-31707 or U.S. Pat. No. 5,976,934, U.S. Pat. No. 5,986,302).

However, the charge leak protect film 83 interposed between the base of the floating gate electrode 92 and the semiconductor substrate in vicinity of edge portion of the floating gate electrode 92, because the leak protect film 83 is considerably thicker than the gate oxide film 91. That is, what is called gate bird's beak is formed therebetween. Then, the charge leak protect film 82 became considerably thick at a portion between a impurity region 85 and edge or corner portion of the base of the floating gate electrode 92. Thereby, as shown in FIG. 8, an electric charge went through a distance between the impurity region 85 and the corner portion of the base of the floating gate electrode 92. As a result, there was a problem that mobility of electric charge was small.

Therefore, the present invention aimed at providing a method of manufacturing a semiconductor device wherein formation of the gate bird's beak is restrained.

### SUMMARY OF THE INVENTION

The present invention adopts following configuration to solve above problem.

That is, there is provided a method of manufacturing a semiconductor device comprising steps of providing a semiconductor substrate, forming a gate oxide film over the semiconductor substrate, forming a stacked gate structure on the gate oxide film comprising a floating gate electrode and a control gate electrode with a gate insulating film interposed therebetween, forming a charge leak protect film comprising oxide film with a heat-treatment around the stacked gate structure on the gate oxide film so that the charge leak protect film becomes as thick as the gate oxide film, forming a side wall on a vertical surface of the charge leak protect film, and treating the charge leak protect film with a heat-treatment so that the charge leak protect film becomes thicker than the gate oxide film.

According to the present invention, heat-oxidation of surface of semiconductor substrate beneath base of floating gate electrode can be restrained so as not to form a large gate bird's beak, because side wall on charge leak protect film becomes a shield against heat-oxidation, as heat-oxidation treatment is performed after forming the side wall. Thereby, a semiconductor device with good electric charge mobility can be obtained.

Further, according to the present invention, semiconductor device mentioned above can be manufactured at low cost so as to restrain investment in equipment, because manufacturing method mentioned above needs no additional apparatus.

### BRIEF DESCRIPTION OF THE DRAWINGS

FIG. 1 is a sectional view showing a structure of semiconductor device formed by a method of present invention.

FIG. 2 is an enlarged sectional view showing a structure of a chief portion of semiconductor device formed by a method of present invention.

FIG. 3 is a sectional view showing a structure of a stacked gate of semiconductor device formed by a method of present invention.

FIG. 4 is a sectional view showing a structure of a stacked gate with charge leak protect film formed by a method of present invention.

FIG. 5 is a sectional view showing a structure of a stacked gate with charge leak protect film and side wall formed by a method of present invention.

FIG. 6 is a sectional view showing a structure of a stacked gate with charge leak protect film treated with heat protected by side wall according to a method of present invention.

FIG. 7 is a sectional view showing a structure of semiconductor device formed by a method of present invention connected with wiring.

FIG. 8 is an enlarged sectional view showing a structure of a chief portion of semiconductor device of prior art.

### DESCRIPTION OF THE PREFERRED EMBODIMENTS

Hereinafter, preferred Embodiments of present invention will be described, referring to the drawings.

### EMBODIMENT

<Configuration>

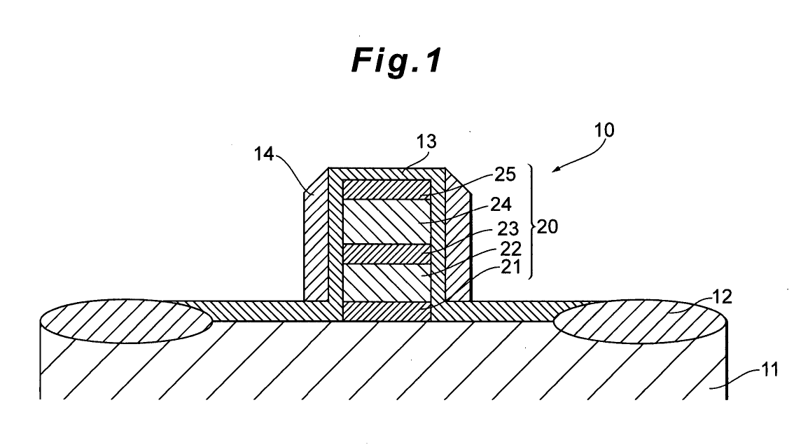

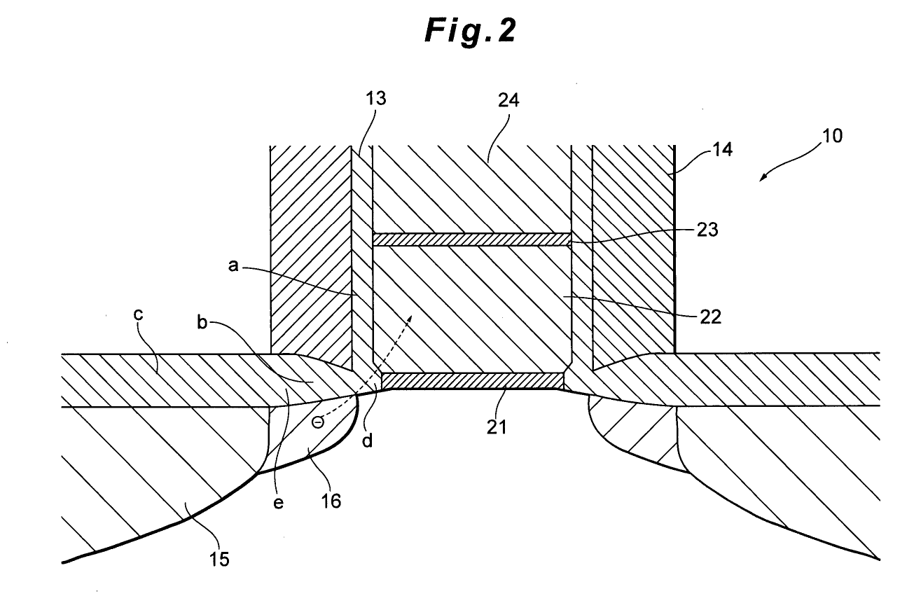

A semiconductor device formed by present invention is, for example, a non-volatile memory. A cell of the non-volatile memory is shown in FIG. 1 about structure of the cell. Moreover, a charge leak protect film beneath base of side wall shown in FIG. 1, is shown in detail drawing of FIG. 2, featuring the present invention.

A semiconductor device 10 according to the present invention, as shown in FIG. 1, comprises a stacked gate structure 20, a charge leak protect film 13, a pair of side walls 14.

The stacked gate structure 20 comprises a gate oxide film 21 formed over a semiconductor substrate 11. That is, a pair of isolation region 12 is formed on the semiconductor substrate 11 comprising silicon. Then, surface of the semiconductor substrate 11 is divided into active region. And, on a prescribed portion of the active region, the stacked gate structure 20 is formed.

A charge leak protect film 13 covers the stacked gate structure 20.

A pair of side walls 14 are formed on a vertical surface of the charge leak protect film 13.

Although not shown in FIG. 1, as shown in detail drawing of FIG. 2, a pair of impurity region 15 is formed in the active region. The impurity region 15 has an LDD (Lightly Doped Drain) structure for restraining hot carrier, so as to comprise source and drain. And, the impurity region 15 is positioned at each side of the stacked gate structure 20. Further, a pair of extended impurity region 16 is formed extending from each impurity region 15 to each end of a channel region between source and drain.

Moreover, the stacked gate structure 20 further comprises a floating gate electrode 22, a gate insulating film 23 and a control gate electrode 24, so as to make up a multi-layered structure deposited plural layers of plural kinds. The floating gate electrode 22 is for containing electric charge. The gate insulating film 23 is for holding the electric charge contained in the floating gate electrode 22. And, the control gate electrode 24 is for controlling mobility of electric charge between the floating gate electrode 22 and the extended impurity region 16. Further, a hard mask of oxide film 25 is for patterning the stacked gate structure 20.

Here, the charge leak protect film 13 covering the stacked gate structure 20 is described referring to the detail figure of FIG. 2. Thickness of the charge leak protect film 13 is different corresponding to position where the charge leak protect film 13 is formed. It is the thinnest on top surface of the stacked gate structure 20 and at side of the stacked gate structure 20 (position designated “a” in FIG. 2). The middle thinnest is on top surface of the extended impurity region 16, that is, beneath base surface of the side wall 14 (position designated “b” in FIG. 2). The thickest is on top surface of the impurity region 15 (position designated “c” in FIG. 2).

The charge leak protect film 13 with different thickness corresponding to the position a, b, c is made as follows. At first, the charge leak protect film 13 of even thickness is formed all over the semiconductor substrate. Thereafter, at a prescribed position on surface of the charge leak protect film 13, that is, at both sides of the stacked gate structure covered with the charge leak protect film 13, a pair of side walls 14 are formed. Then, a heat-treatment is performed. Thereby, growth of the charge leak protect film 13 is restrained, because heat conduction of the heat-treatment is shielded at position “a” and “b” in FIG. 2.

That is, first at position “a”, second at position “b”, thin charge leak protect film 13 is formed, because oxidation of the charge leak protect film 13 is restrained in this order.

On the other hand, the charge leak protect film 13 at position “c” not shielded by the side wall 14, is formed thicker than at position “a” and “b”, because the charge leak protect film 13 directly receives the heat conduction of heat-treatment at position “c”.

Here, further detail structure of the charge leak protect film 13 will be described referring to FIG. 2.

Edge of base of the floating gate electrode 22 is chamfered by the heat-treatment, because silicon included in the floating gate electrode 22 is oxidized by the heat-treatment. This chamfered portion comprises silicon oxide as same as the charge leak protect film 13. Therefore, this chamfered portion becomes a portion of the charge leak protect film 13. Moreover, the gate oxide film 21 comprises silicon oxide as same as the charge leak protect film 13. Therefore, division line between the charge leak protect film 13 and the gate oxide film 21 in FIGS. 1 and 2, is unnecessary.

At position “d” of the charge leak protect film 13 shown in FIG. 2, thickness of the charge leak protect film 13 gradually decreases from end of the extended impurity region 16 toward channel region between source and drain. And, at position “e” of the charge leak protect film 13 shown in FIG. 2, thickness of the charge leak protect film 13 gradually decreases toward the channel region. Therefore, formation of gate bird's beak is restrained.

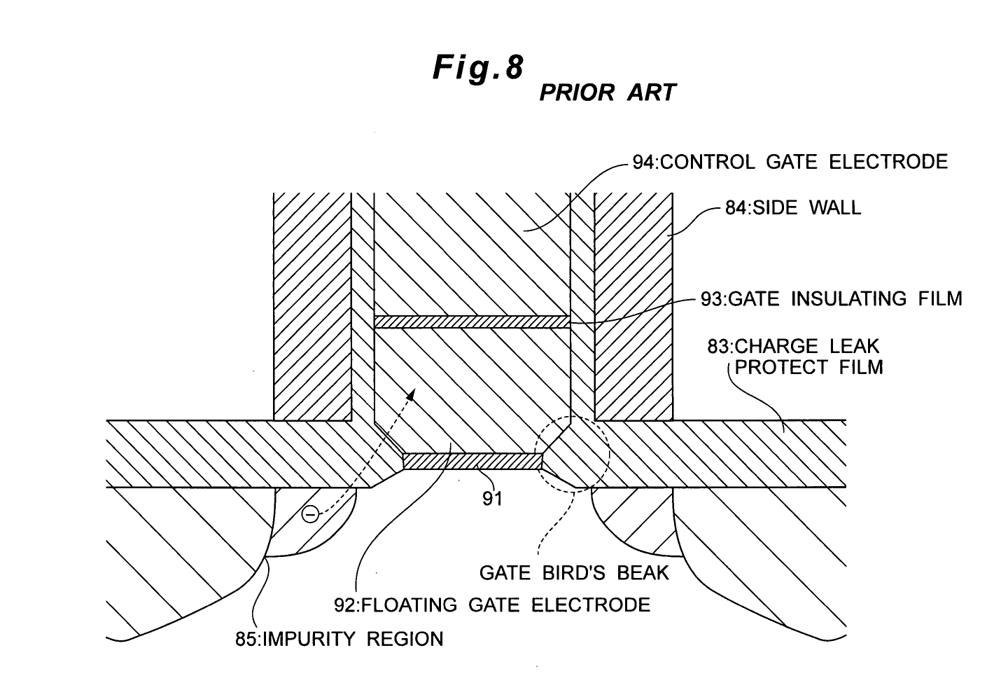

Here, the conventional charge leak protect film 83 with gate bird's beak will be described referring to FIG. 8. Gate bird's beak is a name of sectional figure of silicon oxide layer like a beak of a bird. Since, thickness of silicon oxide layer considerably decreases from outer end of the base of the floating gate electrode 92 toward central portion of channel region. The reason why gate bird's beak of this kind is formed, is that the charge leak protect film 83 is formed thicker than a prescribed thickness. As a result, the charge leak protect film 83 between the floating gate electrode 92 and impurity region 84 for source or drain, becomes considerably thick, as shown in FIG. 8. And, electric charge mobility therebetween, considerably deteriorated. However, according to present invention, as mentioned above, side wall 14 becomes a shield against heat-oxidation treatment. And, growth of gate bird's beak is restrained. As a result, a portion of the charge leak protect film 83 having thickness to deteriorate electric charge mobility, is not formed.

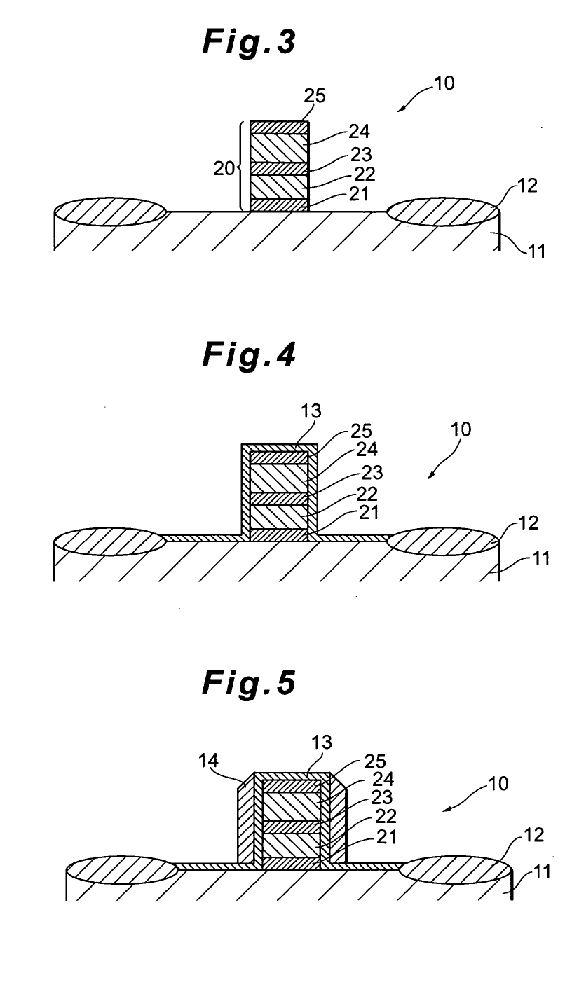

A process of manufacturing semiconductor device is shown in FIG. 3 to 7 in this order. And, according to these figures, a method of manufacturing a semiconductor device of present invention will be described.

At first, a semiconductor substrate is provided, and a pair of an isolating region 12 is formed so as to form an active region at a prescribed position on surface of semiconductor substrate 11. The isolating region 12 is formed by a method of LOCOS (Local Oxidation of Silicon) or STI (Shallow Trench Isolation) hitherto known. Thereafter, a layer for a gate oxide film 21 is formed on the active region on the semiconductor substrate at a thickness of, for example, 50 to 100 angstroms. Then, a poly-silicon layer for a floating gate electrode 22 is formed on the layer for a gate oxide film 21 by a method of, for example, CVD (Chemical Vapor Deposition).

After a poly-silicon layer for a floating gate electrode 22 is formed, a layer for a gate insulating film 23, for example, an oxide layer is formed. And, a layer for a control gate electrode 24, for example, a poly-silicon layer is formed on surface of the oxide layer. After stacking these layers, that is, an oxide layer (21), a poly-silicon layer (22), an oxide layer (23), and a poly-silicon layer (24), a hard mask 25, for example, silicon dioxide layer of a prescribed pattern is formed, so as to perform patterning of these layers. Thereafter, an etching is performed so as to form a stacked gate structure 20 shown in FIG. 3.

After forming a stacked gate structure 20 at a prescribed position on the active region, a heat-oxidation treatment is performed so as to form an oxide film at a thickness of, for example, 0 to 100 angstroms covering the stacked gate structure 20. By the heat-oxidation treatment mentioned above, a charge leak protect film 13 is formed, as shown in FIG. 4.

After the heat-oxidation treatment mentioned above, an oxide layer for a side wall 14 is formed at a thickness of about 300 to 1000 angstroms, so as to form a side wall 14 on a vertical surface of the charge leak protect film 13 covering the stacked gate structure 20. And, an etch-back treatment is performed to the oxide layer for a side wall 14, so as to form a prescribed shape of side wall 14, as shown in FIG. 5. Therefore, the side wall 14 has a thickness of about 300 to 1000 angstroms.

After forming the side wall 14, a heat-oxidation treatment is performed, the charge leak protect film 13 formed as mentioned above, is further deposited. Thereby, the charge leak protect film 13 having a thickness of about 100 to 200 angstroms at position “b”, is formed, after all. To be concrete, a thickness of the charge leak protect film 13 at position “c” shown in FIG. 2, is a half of the thickness of the side wall 14.

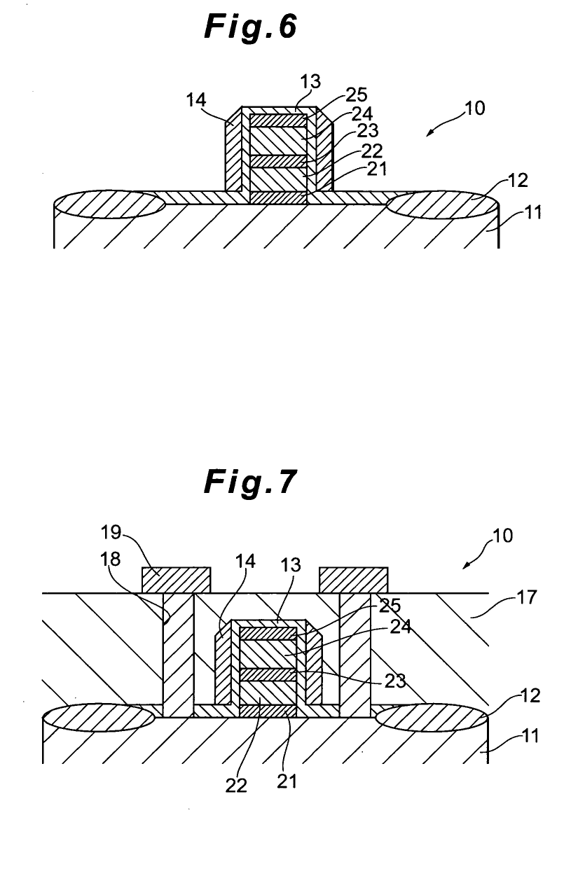

The charge leak protect film 13 has a thickness thicker than the gate oxide film 21, as shown in FIG. 6.

Thereby, the edge of the base of the floating gate electrode 22 is surrounded with the charge leak protect film 13 in horizontal direction. Therefore, leak of electric charge from the base of the electrode can be prohibited. As a result, a semiconductor device having a feature of good charge hold can be obtained.

Moreover, the side wall 14 becomes a shield of a heat-oxidation treatment. Therefore, growth of gate bird's beak can be restrained. As a result, a semiconductor device having a feature of good electric charge mobility can be obtained.

The process time of this heat-oxidation treatment of the charge leak protect film 13, is decided corresponding to thickness of the gate oxide film 21, thickness of the side wall 14, and structure of neighboring semiconductor device.

After the heat-oxidation treatment, an ion implantation is performed, so as to form an intermediate insulating film 17. The intermediate insulating film 17 is an oxide film covering element isolating region, charge leak protect film 13, and side wall 14, all over uniformly.

After forming the intermediate insulating film 17, contact hole 18 for contacting electrically with source and drain, is formed, as shown in FIG. 7. And, aluminum alloy or tungsten alloy etc. is filled with the contact hole 18. Thereby, metal wiring 19 is formed. In this occasion, other metal wiring (not shown in the drawings) for obtaining electrical contact is formed with the control gate electrode 24.

<Effects>

As mentioned above, according to the method of manufacturing semiconductor device 10 of present invention, growth of charge leak protect film 13, that is, formation of gate bird's beak at a portion, where an atmosphere of heat-oxidation treatment is shielded, can be restrained; because heat of heat-oxidation treatment is shut off with side wall 14, that is, atmosphere of heat-oxidation treatment is shut off with side wall 14, as heat-oxidation treatment is performed after forming the side wall 14 at a prescribed position on the charge leak protect film 13. As a result, a semiconductor device having a feature of good electric charge mobility can be obtained.

Moreover, according to the method of manufacturing device of present invention, investment in equipment can be restrained, because the semiconductor device 10 mentioned above can be manufactured without any special manufacturing device. As a result, a semiconductor device with low price and high performance, can be manufactured.

### OTHER EMBODIMENTS

Although, the side wall 14 is formed by performing etch back treatment to the oxide layer deposited, the side wall 14 can be formed with nitride film instead of oxide film. Atmosphere of heat-oxidation treatment going round through the edge of base of side wall, can be restrained by forming the side wall with nitride film. Thereby, control of the process time of performing heat-oxidation treatment, can be performed easily. As a result, a semiconductor device with restrained gate bird's beak formation can be obtained easily.

Moreover, each structure other than the side wall, can be modified properly.

1. A method of manufacturing a semiconductor device comprising steps of:
providing a semiconductor substrate,
forming a gate oxide film over the semiconductor substrate,
forming a stacked gate structure on the gate oxide film comprising a floating gate electrode and a control gate electrode with a gate insulating film interposed therebetween,
forming a charge leak protect film comprising oxide film with a heat-treatment around the stacked gate structure on the gate oxide film so that the charge leak protect film becomes as thick as the gate oxide film,
forming a side wall on a vertical surface of the charge leak protect film,
and treating the charge leak protect film with a heat-treatment so that the charge leak protect film becomes thicker than the gate oxide film.

2. A method of manufacturing a semiconductor device according to claim 1 wherein the side wall comprises an oxide film.

3. A method of manufacturing a semiconductor device according to claim 1 wherein the side wall comprises a nitride film.
